(19) United States
(12) Patent Application Publication
(10) Pub. No.: US 2026/0068409 A1
(43) Pub. Date: Mar. 5, 2026

(54) METHOD OF MANUFACTURING LIGHT-EMITTING DEVICE, AND LIGHT-EMITTING DEVICE

(71) Applicant: Nichia Corporation, Anan-shi (JP)

(72) Inventors: Kazusa NISHIUCHI, Anan-shi (JP); Koji ABE, Tokushima-shi (JP)

(73) Assignee: Nichia Corporation, Anan-shi (JP)

(21) Appl. No.: 19/310,332

(22) Filed: Aug. 26, 2025

(30) Foreign Application Priority Data
Sep. 4, 2024 (JP) 2024-152444

(51) Int. Cl. H10H 29/855; H10H 29/01; H10H 29/24

(52) U.S. Cl. CPC H10H 29/8552; H10H 29/0363; H10H 29/24

(57) ABSTRACT

A method of manufacturing a light-emitting device includes: providing a first structure including a first support substrate, a release portion, and a light-transmissive portion, in this order; providing a second structure including a second support substrate, and light-emitting elements temporarily fixed to the second support substrate, each including electrodes at its lower surface, and being temporarily fixed to the second support substrate via a temporary fixing layer; transferring the light-emitting elements to the light-transmissive portion by irradiating the temporary fixing layer with laser light; forming a light-shielding portion between the light-emitting elements; bonding the electrodes to the substrate; disposing a resin portion in at least a part of an area between each of the light-emitting elements and the substrate, in which a concentration of a filler contained in the resin portion is lower than that in the light-shielding portion; and releasing the first support substrate from the first structure.

### CROSS REFERENCE TO RELATED APPLICATION

This application claims priority to Japanese Patent Applications No. 2024-152444, filed on Sep. 4, 2024, the entire contents of which are hereby incorporated by reference.

### BACKGROUND

### Technical Field

The present disclosure relates to a method of manufacturing a light-emitting device, and the light-emitting device.

### Background Art

For example, a method of manufacturing a monochromatic chip-scale package type light-emitting diode element has been disclosed as including the following steps. First, a release layer is prepared, and an upper light-transmissive layer and a photoluminescence layer are sequentially disposed and laminated on the release layer by using manufacturing steps involving spraying, printing, or molding. Subsequently, a photoluminescence sheet is disposed on the release layer with the photoluminescence layer facing upward. A plurality of LED semiconductor dies are arranged in an array on the photoluminescence layer such that upper surfaces of the plurality of LED semiconductor dies face downward and are covered by the photoluminescence layer. Reflective structures are disposed inside grooves to cover edge surfaces of the plurality of LED semiconductor dies and edge surfaces of photoluminescence structures. For example, see Japanese Patent Publication No. 2017-168819.

### SUMMARY

An object of the present disclosure is to provide a method of manufacturing a light-emitting device that can improve reliability, and to provide the light-emitting device.

A method of manufacturing a light-emitting device according to an embodiment of the present disclosure includes: providing a first structure comprising a first support substrate, a release portion, and a light-transmissive portion in this order; providing a second structure comprising a second support substrate and a plurality of light-emitting elements temporarily fixed to the second support substrate, each of the plurality of light-emitting elements having an upper surface and a lower surface, each of the plurality of light-emitting elements comprising a plurality of electrodes at the lower surface, and being temporarily fixed, at the lower surface thereof, to the second support substrate via a temporary fixing layer; transferring the plurality of light-emitting elements to the light-transmissive portion by arranging the light-transmissive portion in the first structure and the upper surface of each of the plurality of light-emitting elements, which are temporarily fixed to the second support substrate, to face each other, and irradiating the temporary fixing layer with laser light; forming a light-shielding portion between the plurality of light-emitting elements, the light-shielding portion containing a filler; bonding the electrodes of the plurality of light-emitting elements to the substrate; disposing a resin portion containing a filler in at least a part of an area between each of the plurality of light-emitting elements and the substrate, in which a concentration of a filler contained in the resin portion is lower than a concentration of a filler contained in the light-shielding portion; and releasing the first support substrate from the first structure.

A light-emitting device according to an embodiment of the present disclosure includes: a substrate; a plurality of light-emitting elements disposed on the substrate; a light-shielding portion disposed between the plurality of light-emitting elements, and covering lateral surfaces of each of the plurality of light-emitting elements; a resin portion disposed in at least a part of an area between the plurality of light-emitting elements and the substrate, and disposed between the light-shielding portion and the substrate; and a light-transmissive portion covering upper surfaces of the plurality of light-emitting elements. Each of the light-shielding portion and the resin portion contains a filler, and a concentration of a filler contained in the resin portion is lower than a concentration of a filler contained in the light-shielding portion.

According to an embodiment of the present disclosure, a method of manufacturing a light-emitting device that can improve reliability, and the light-emitting device can be provided.

### BRIEF DESCRIPTION OF DRAWINGS

FIG. 1 is a schematic perspective view illustrating a light-emitting device according to one embodiment.

FIG. 2 is a schematic perspective view illustrating the light-emitting device according to one embodiment, with a part of the configuration omitted.

FIG. 3 is a schematic top view illustrating the light-emitting device according to one embodiment.

FIG. 4 is a schematic cross-sectional view taken along the line IV-IV in FIG. 3.

FIG. 5 is a partially enlarged view of light-emitting elements illustrated in FIG. 4 and the vicinity of the light-emitting elements.

FIG. 6A is a schematic cross-sectional view illustrating a manufacturing step of the light-emitting device according to one embodiment.

FIG. 6B is a schematic cross-sectional view illustrating a manufacturing step of the light-emitting device according to one embodiment.

FIG. 6C is a schematic cross-sectional view illustrating a manufacturing step of the light-emitting device according to one embodiment.

FIG. 6D is a schematic top view illustrating a manufacturing step of the light-emitting device according to one embodiment.

FIG. 6E is a schematic cross-sectional view illustrating a manufacturing step of the light-emitting device according to one embodiment.

FIG. 6F is a schematic cross-sectional view illustrating a manufacturing step of the light-emitting device according to one embodiment.

FIG. 6G is a schematic cross-sectional view illustrating a manufacturing step of the light-emitting device according to one embodiment.

FIG. 6H is a schematic cross-sectional view illustrating a manufacturing step of the light-emitting device according to one embodiment.

FIG. 6I is a schematic cross-sectional view illustrating a manufacturing step of the light-emitting device according to one embodiment.

FIG. 7 is a partially enlarged view of light-emitting elements and the vicinity of the light-emitting elements in the light-emitting device according to a first modified example.

FIG. 8 is a partially enlarged view of light-emitting elements and the vicinity of the light-emitting elements in the light-emitting device according to a second modified example.

### DETAILED DESCRIPTION

A light-emitting device according to the present disclosure (hereinafter, may be referred to as a “light-emitting device according to an embodiment”) will be described below with reference to the drawings. In the following descriptions, terms indicating a specific direction or position (for example, “upper,” “lower,” and other terms including those terms) are used as necessary. However, the use of those terms is to facilitate understanding of the invention with reference to the drawings, and the technical scope of the present disclosure is not limited by the meanings of those terms. Portions having the same reference characters appearing in a plurality of drawings indicate identical or equivalent portions or members.

Further, the following embodiments exemplify a light-emitting device and the like for embodying the technical concepts of the present invention, but the present invention is not limited to the described embodiments. The dimensions, materials, shapes, relative arrangements, and the like of constituent components described below are not intended to limit the scope of the present invention to those alone, but are intended to provide an example, unless otherwise specified. The contents described in an embodiment can be applied to any of the other embodiments and modified examples. The sizes, the positional relationship, and the like of the members illustrated in the drawings may be exaggerated to clarify the explanation. Furthermore, to avoid excessive complication of the drawings, a schematic view in which some elements are not illustrated may be used, or an end view illustrating only a cutting surface may be used as a cross-sectional view.

### Embodiment

A light-emitting device according to one embodiments of the present disclosure includes: a substrate; a plurality of light-emitting elements disposed on the substrate; a light-shielding portion provided between the plurality of light-emitting elements, and covering lateral surfaces of each of the plurality of light-emitting elements; a resin portion provided in at least a part of an area between the plurality of light-emitting elements and the substrate, and provided between the light-shielding portion and the substrate; and a light-transmissive portion covering upper surfaces of the plurality of light-emitting elements, in which the light-shielding portion and the resin portion both contain a filler, and a concentration of a filler contained in the resin portion is lower than a concentration of a filler contained in the light-shielding portion.

### Light-Emitting Device 1

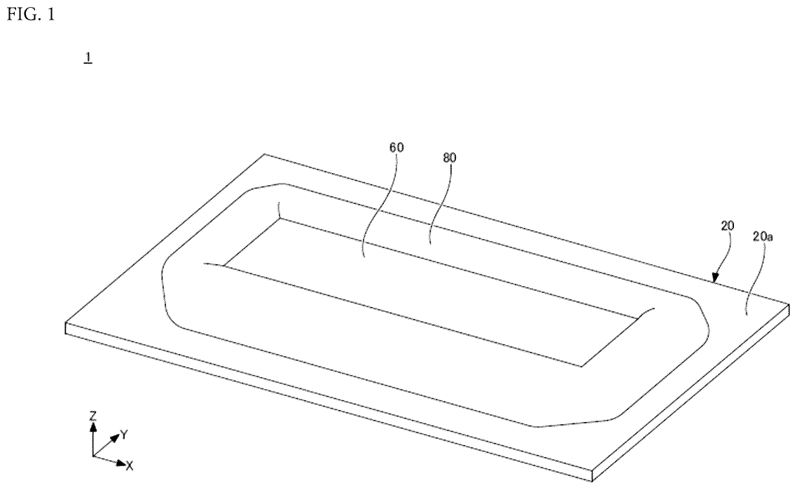

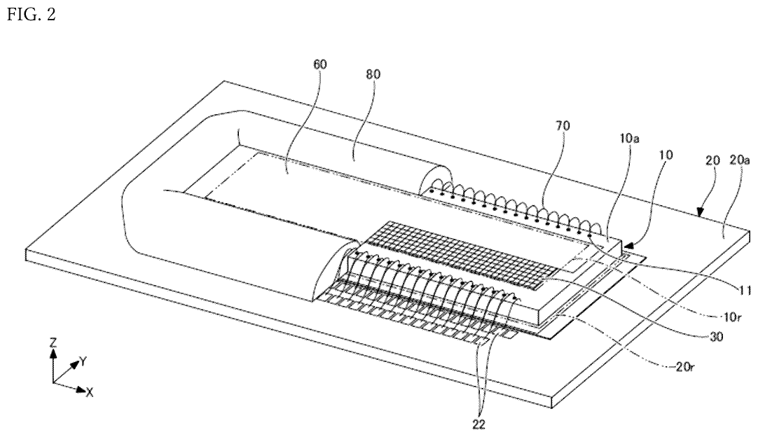

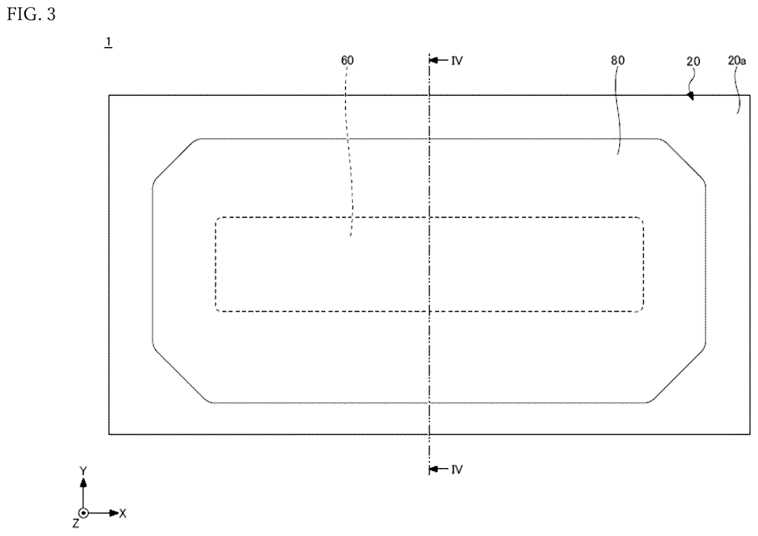

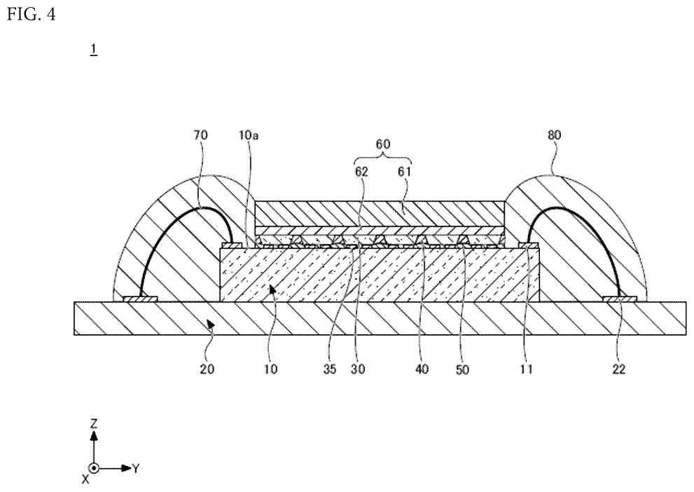

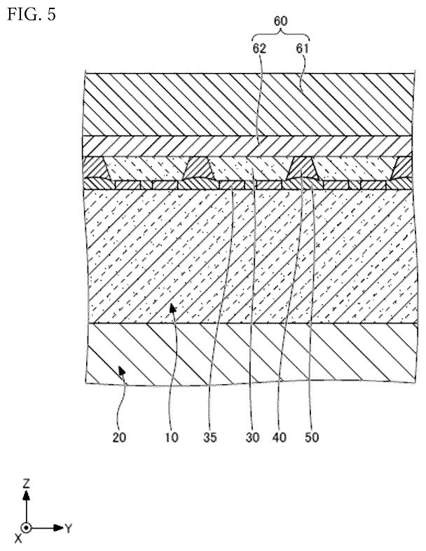

A light-emitting device 1 will be described as an example of the light-emitting device according to the present disclosure. FIG. 1 is a schematic perspective view illustrating a light-emitting device according to the present embodiment. FIG. 2 is a schematic perspective view illustrating the light-emitting device according to the present embodiment, with a part of the configuration omitted. FIG. 3 is a schematic top view illustrating the light-emitting device according to the present embodiment. FIG. 4 is a schematic cross-sectional view taken along the line IV-IV in FIG. 3. FIG. 5 is a partially enlarged view of the light-emitting elements in FIG. 4 and the vicinity of the light-emitting elements.

In each of the drawings, an X-axis, a Y-axis, and a Z-axis orthogonal to one another are illustrated for reference as necessary. A direction parallel to the X-axis is referred to as an X direction. A direction parallel to the Y-axis is referred to as a Y direction. A direction parallel to the Z-axis is referred to as a Z direction. In addition, in the X direction, a direction in which an arrow is directed is referred to as a +X direction, and a direction opposite to the +X direction is referred to as a −X direction. In the Y direction, a direction in which an arrow is directed is referred to as a +Y direction, and a direction opposite to the +Y direction is referred to as a −Y direction. In the Z direction, a direction in which an arrow is directed is referred to as a +Z direction, and a direction opposite to the +Z direction is referred to as a −Z direction. However, these directions do not limit the orientation of the light-emitting device during use, and any orientation of the light-emitting device may be employed. Furthermore, a view in which a target object is viewed from the +Z direction toward the −Z direction is referred to as a top view.

As exemplified in FIGS. 1 to 5, the light-emitting device 1 includes a substrate 10, a plurality of light-emitting elements 30, a light-shielding portion 40, a resin portion 50, and a light-transmissive portion 60.

The plurality of light-emitting elements 30 are disposed on the substrate 10. The plurality of light-emitting elements 30 can be disposed, for example, in a matrix form in a top view. The plurality of light-emitting elements 30 can be individually driven. The plurality of light-emitting elements 30 may be individually driven, for example, by using the substrate 10 as a semiconductor integrated circuit substrate such as an application specific integrated circuit (ASIC), or may be individually driven by an electric circuit provided outside the light-emitting device 1.

The light-shielding portion 40 is provided between adjacent ones of the plurality of light-emitting elements 30 and covers lateral surfaces of each of the plurality of light-emitting elements 30. The light-shielding portion 40 is made of a resin containing a filler. The filler contained in the light-shielding portion 40 has, for example, light reflectivity. With the light-shielding portion 40 covering the lateral surfaces of each of the plurality of light-emitting elements 30, light emitted from the lateral surfaces of the plurality of light-emitting elements 30 can be reflected toward the light-transmissive portion 60. Therefore, the light extraction efficiency is increased, and the luminance of the light-emitting device 1 can be improved.

For example, an upper surface of the light-shielding portion 40 is flat. A lower surface of the light-shielding portion 40 may or may not be flat. In the illustrated example, the light-shielding portion 40 is in a fillet shape between adjacent ones of the plurality of light-emitting elements 30, for example. In this case, the lower surface of the light-shielding portion 40 is a curved surface that is convex toward an upper surface. With the light-shielding portion 40 in a fillet shape, the entire lateral surfaces of the light-emitting elements 30 can be covered with the light-shielding portion 40 even when the thickness of part of the light-shielding portion 40 is less than the thickness of the light-emitting elements 30. This allows for improving the efficiency that the light-shielding portion 40 reflects light emitted from the lateral surfaces of the plurality of light-emitting elements 30.

The resin portion 50 is provided in at least a part of the area between the plurality of light-emitting elements 30 and the substrate 10, and provided between the light-shielding portion 40 and the substrate 10. An upper surface of the resin portion 50 is in contact with, for example, the lower surface of each of the plurality of light-emitting elements 30, and the lower surface of the light-shielding portion 40. The resin portion 50 covers a portion or an entirety of a lateral surface of an electrode 35 of the light-emitting elements 30. The resin portion 50 contains a filler. The filler contained in the resin portion 50 has, for example, light reflectivity. A concentration of the filler contained in the resin portion 50 is lower than a concentration of the filler contained in the light-shielding portion 40. In the present specification, the concentration of the filler in the light-shielding portion 40 indicates a ratio of weight of the filler contained in the light-shielding portion 40 to the weight of the light-shielding portion 40, and is expressed using a unit of wt. %. In addition, the concentration of the filler in the resin portion 50 indicates a ratio of weight of the filler contained in the resin portion 50 to the weight of the resin portion 50, and is expressed using a unit of wt. %.

The light-transmissive portion 60 covers upper surfaces of the plurality of light-emitting elements 30. In addition, the light-transmissive portion 60 covers the upper surface of the light-shielding portion 40. In the illustrated example, the light-transmissive portion 60 includes a second region 62 provided on the upper surface of each of the plurality of light-emitting elements 30 and not including a wavelength conversion member, and a first region 61 provided on the second region 62 and including the wavelength conversion member. The second region 62 transmits light incident from the light-emitting elements 30. The first region 61 converts light incident from the light-emitting elements 30 via the second region 62 into light having a different wavelength and emits the light. The first region 61 may be configured such that a part of the light incident on the first region 61 via the second region 62 is emitted from the first region 61 without being converted into light having a different wavelength, or may be configured such that an entirety of the light incident on the first region 61 via the second region 62 is emitted from the first region 61 after being converted into light having a different wavelength. When there is no need for wavelength conversion, the light-transmissive portion 60 does not necessarily include the first region 61 including the wavelength conversion member.

Further, the light-emitting device 1 may include a package substrate 20, wires 70, and a covering member 80. In the examples of FIGS. 1 to 5, the substrate 10 is mounted on an upper surface 20a of the package substrate 20. First terminals 11 are disposed on the upper surface 10a of the substrate 10 outside a region where the plurality of light-emitting elements 30 are disposed. The package substrate 20 is larger than the substrate 10 in a top view. Second terminals 22 are disposed on the upper surface 20a of the package substrate 20 outside a region where the substrate 10 is mounted. Each of the first terminals 11 of the substrate 10 is electrically connected by a corresponding one of the wires 70 to a corresponding one of the second terminals 22 of the package substrate 20. The first terminals 11, the second terminals 22, and the wires 70 are covered by the covering member 80 disposed on an outer peripheral portion of the upper surface 10a of the substrate 10, and on an outer peripheral portion of the upper surface 20a of the package substrate 20. The light-transmissive portion 60 may be located inside the covering member 80 in a top view.

In FIG. 2, for convenience of illustration, a part of the light-transmissive portion 60 and a part of the covering member 80 are omitted, and some of the light-emitting elements 30 and the wires 70, and other components are visualized.

In the light-emitting device 1, the resin portion 50 provided at least partially between the plurality of light-emitting elements 30 and the substrate 10 allows for increasing the connection strength between the light-emitting elements 30 and the substrate 10, and thus the reliability of the light-emitting device 1 can be improved. In addition, the resin portion 50 provided in at least a part of the area between the plurality of light-emitting elements 30 and the substrate 10 can reflect light emitted from the lower surfaces of the light-emitting elements 30 toward the light-transmissive portion 60. As a result, light extraction efficiency increases, and the luminance of the light-emitting device 1 can be improved.

In addition, the resin portion 50 provided between the light-shielding portion 40 and the substrate 10 can reflect light leaking from the light-shielding portion 40 toward the light-transmissive portion 60. As a result, light extraction efficiency increases, and the luminance of the light-emitting device 1 can be improved. In particular, in a case in which the concentration of the filler contained in the resin portion 50 is greater than 0 and equal to or less than 30 wt. %, the effect of reflecting the light leaking from the light-shielding portion 40 toward the light-transmissive portion 60 is greatly enhanced.

In addition, with the concentration of the filler contained in the resin portion 50 set lower than the concentration of the filler contained in the light-shielding portion 40, the resin proportion around the electrodes 35 of the light-emitting elements 30 can be increased while improving the light reflection efficiency relative to the light emitted from the lateral surfaces of the light-emitting elements 30. Therefore, occurrence of cracks in the resin portion 50 due to thermal shock or the like can be reduced.

The constituent components of the light-emitting device 1 are described below.

### Substrate 10

The substrate 10 includes a support member having a flat plate shape and a conductive member disposed on an upper surface side of the support member. The upper surface 10a of the substrate 10 has an element placement region 10r in which the plurality of light-emitting elements 30 are placed, and the conductive member is disposed in the element placement region 10r. The substrate 10 includes a plurality of first terminals 11 disposed on the upper surface 10a on an outer side of the element placement region 10r, and the first terminals 11 are electrically connected to the conductive member disposed in the element placement region 10r.

For example, in a top view, the substrate 10 and the element placement region 10r may each have a rectangular shape having long sides and short sides. The plurality of light-emitting elements 30 are placed in a matrix form in the element placement region 10r, for example. Each of the plurality of light-emitting elements 30 is electrically connected to any one of the first terminals 11. For example, the plurality of light-emitting elements 30 can be connected in series or in parallel with the first terminals 11, as a group including a predetermined number of light-emitting elements 30. The length of the long sides of the element placement region 10r can be in a range from 8 mm to 18 mm, and the length of the short sides can be in a range from 2 mm to 6 mm, for example.

Each of the first terminals 11 has a substantially circular shape, a substantially elliptical shape, or a substantially rectangular shape, for example. The first terminals 11 are disposed on the upper surface 10a of the substrate 10 in a row along the opposing long sides of the element placement region 10r having a rectangular shape, so that the first terminals 11 are spaced apart from one another and sandwich the element placement region 10r. An interval between adjacent ones of the first terminals 11 may be constant or may not be constant. The interval between adjacent ones of the first terminals 11 can be in a range from 20 μm to 100 μm, for example. One end of the wire 70 is connected to each of the first terminals 11.

The substrate 10 is, for example, a semiconductor substrate such as a silicon substrate. A region of the upper surface 10a of the substrate 10 where no conductive member is disposed is covered with an insulating film, for example. The conductive member may also be disposed inside the support member or on a lower surface of the support member. For example, an integrated circuit substrate with an integrated circuit for individually driving and controlling the plurality of light-emitting elements 30 may be used as the substrate 10.

Examples of the material of the first terminals 11 and the conductive member include metals such as Cu, Ag, Au, Al, Pt, Ti, W, Pd, Fe, and Ni, and/or alloys containing at least any of these metals.

### Package Substrate 20

The package substrate 20 includes a base body having a flat plate shape, and a conductive member disposed at least on an upper surface side of the base body. The package substrate 20 includes, on the upper surface 20a, a substrate placement region 20r where the substrate 10 is placed, and further includes the second terminals 22 on the upper surface 20a on an outer side of the substrate placement region 20r. The substrate placement region 20r is a region where the substrate 10 is placed. The substrate placement region 20r is set as a region having an area substantially equal to the area of the shape of the substrate 10 in a top view. When the substrate 10 is rectangular in a top view, the substrate placement region 20r may also be rectangular. Here, the meaning of “substantially equal” includes, as an acceptable range, an error caused by member tolerance and mounting tolerance.

Each of the second terminals 22 has a substantially circular shape, a substantially elliptical shape, or a substantially rectangular shape, for example. The second terminals 22 are disposed on the upper surface 20a of the package substrate 20 in a row along the opposing long sides of the rectangular shape, so that the second terminals 22 are spaced apart from one another and sandwich the substrate placement region 20r. An interval between adjacent ones of the second terminals 22 may be constant or may not be constant. The interval between adjacent ones of the second terminals 22 can be in a range from 20 μm to 100 μm, for example. The other end of the wire 70 is connected to each of the second terminals 22.

A material having high heat dissipation is preferably used for the base body constituting the package substrate 20.

A material having high light-shielding properties and high base body strength is more preferably used. Specific examples of the material include metals such as Al and Cu; ceramics such as aluminum oxide, aluminum nitride, silicon nitride, and mullite; resins such as phenol resin, epoxy resin, polyimide resin, bismaleimide triazine resin (BT resin), and polyphthalamide (PPA), and further, graphite, and composite materials made from a resin and a metal or a ceramic (for example, an inlay substrate obtained by fitting metal members into a resin). The base body having a flat plate shape can be used, or a base body including a recessed portion on an upper surface may be used. In this case, the bottom of the recessed portion can serve as the substrate placement region 20r of the package substrate 20, and the substrate 10 can be placed inside the recessed portion.

The package substrate 20 may include a conductive member for placing the substrate 10 on the surface of the substrate placement region 20r.

### Light-Emitting Element

Each of the light-emitting elements 30 can have, for example, a square shape having one side length in a range from 40 μm to 100 μm in a top view. The light-emitting element 30 includes positive and negative electrodes 35 on the same surface side, and is flip-chip mounted on the substrate 10 with the surface having the electrodes 35 as the lower surface. In this case, the upper surface positioned on an opposite side to the surface where the electrodes 35 are disposed serves as a main light extracting surface of the light-emitting element 30.

In the light-emitting device 1, the light-emitting elements 30 are placed on the substrate 10 and aligned at predetermined intervals in the row and column directions. The size and the number of the light-emitting elements 30 to be used can be selected as appropriate, depending on the form of the desired light-emitting device. It is preferable to place a larger number of smaller light-emitting elements 30 at a high density. This makes it possible to control the irradiation range of light emitted from the light-emitting device 1 by dividing the irradiation range into a larger number of ranges. Such a light-emitting device 1 can be used as a light source of a high-resolution illumination system. For example, the number of the light-emitting elements 30 included in the light-emitting device 1 can be in a range from 1000 to 100000.

For example, the light-emitting elements 30 are light-emitting diodes. Each of the light-emitting elements 30 has a semiconductor structure. The semiconductor structure includes an n-side semiconductor layer, a p-side semiconductor layer, and an active layer interposed between the n-side semiconductor layer and the p-side semiconductor layer. The active layer may have a single quantum well (SQW) structure, or may have a multi quantum well (MQW) structure including a plurality of well layers. The active layer can emit visible light or ultraviolet light, for example.

The semiconductor structure may include a plurality of light-emitting portions each including an n-side semiconductor layer, an active layer, and a p-side semiconductor layer. When the semiconductor structure includes the plurality of light-emitting portions, the plurality of light-emitting portions may each include well layers having different light emission peak wavelengths, or well layers having the same light emission peak wavelength. The expression “having the same light emission peak wavelength” includes a case in which there is a variation of several nanometers. A combination of the light emission peak wavelengths of the plurality of light-emitting portions can be selected as appropriate. For example, when the semiconductor structure includes two light-emitting portions, combinations of light emitted from the light-emitting portions include a combination of blue light and blue light, a combination of green light and green light, a combination of ultraviolet light and ultraviolet light, a combination of blue light and green light, a combination of blue light and ultraviolet light, and a combination of green light and ultraviolet light. For example, when the semiconductor structure includes three light-emitting portions, combinations of light emitted from the light-emitting portions include a combination of blue light, green light, and red light. Each of the light-emitting portions may include one or more well layers having light emission peak wavelengths different from the light emission peak wavelengths of the other well layers.

As the light-emitting element 30, for example, a light-emitting element that can emit blue light (light having a wavelength in a range from 430 nm to 490 nm) can be employed. Any wavelength can be selected for the color of the light emitted from the light-emitting element 30 in accordance with the application. Examples of the light-emitting element that emits blue light (light having a wavelength in a range from 430 nm to 490 nm) and a light-emitting element that emits green light (light having a wavelength in a range from 495 nm to 565 nm) include a light-emitting element using a nitride-based semiconductor (InₓAl_{y}Ga_{1-x-y}N (0≤x, 0≤y, x+y≤1)), GaP, or the like. Examples of the light-emitting element that emits red light (light having a wavelength in a range from 610 nm to 700 nm) include a light-emitting element using a nitride-based semiconductor element, and also a light-emitting element using GaAlAs, AlInGaP, or the like.

The light-emitting elements 30 are joined by an electrically conductive bonding member onto a conductive member disposed in the element placement region 10r of the substrate 10. In a case in which the light-emitting elements 30 are flip-chip mounted on the substrate 10, a bump made of a metal material such as Au, Ag, Cu, or Al can be used as the bonding member. Furthermore, a solder such as an AuSn-based alloy and an Sn-based lead-free solder may be used as the bonding member. In addition, an electrically conductive adhesive material including electrically conductive particles such as metal particles in a resin can be used as the bonding member. The light-emitting elements 30 and the substrate 10 may be bonded together using a plating method. Examples of the plating material include Cu and Au. Alternatively, the electrodes 35 of the light-emitting elements 30 and the conductive member of the substrate 10 may be in direct contact with each other without interposing the bonding member.

### Light-Shielding Portion

For the light-shielding portion 40, a soft resin having relatively low elasticity and excellent shape conformability is preferably used. A resin material having high transmittance and insulation properties, for example, a thermosetting resin such as an epoxy resin or a silicone resin, can be preferably used as the material of the light-shielding portion 40. In addition, the light-shielding portion 40 preferably uses a resin containing a filler having light reflectivity. Examples of the filler having light reflectivity that can be suitably used include titanium oxide, aluminum oxide, zinc oxide, barium carbonate, barium sulfate, boron nitride, aluminum nitride, and glass. The light-shielding portion 40 may contain a light absorbing member. As the light absorbing member, light absorbing materials such as a pigment, carbon black, titanium black, or graphite can be preferably used.

### Resin Portion

For the resin portion 50, a soft resin having relatively low elasticity and excellent shape conformability is preferably used, similarly to the light-shielding portion 40. As the material for the resin portion 50, a material that is the same as or similar to the material used for the above-described light-shielding portion 40 can be used. In addition, the resin portion 50 preferably uses a resin containing a filler having light reflectivity. As the filler having light reflectivity, a filler that is the same as or similar to the filler used for the above-described light-shielding portion 40 can be used. The resin portion 50 may contain the light absorbing member described above.

### Light-Transmissive Portion

The first region 61 of the light-transmissive portion 60 includes a resin and a wavelength conversion member. Examples of the resin include known resins having transmissivity such as a silicone resin and an epoxy resin. Among these resins, a silicone resin having excellent reliability (specifically, a resin having transmissivity such as a phenyl silicone resin and a dimethyl silicone resin) can be suitably used. Examples of the wavelength conversion member include a phosphor.

Examples of the phosphor include an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), oxynitride-based phosphors such as a β-SiAlON-based phosphor (for example, (Si,Al)₃(O,N)₄:Eu) and an α-SiAlON-based phosphor (for example, Ca(Si,Al)₁₂(O,N)₁₆:Eu), nitride phosphors such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), and an SCASN-based phosphor (for example, (Sr,Ca)AlSiN₃:Eu), fluoride phosphors such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), and an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a II-VI group quantum dot (for example, CdSe), a III-V group quantum dot (for example, InP), and a quantum dot having a chalcopyrite structure (for example, (Ag,Cu)(In,Ga)(S,Se)₂).

In a case in which the light-emitting elements 30 can emit blue light, the first region 61 can contain, for example, a phosphor that is excited by blue light and can emit yellow light. In this case, examples of the phosphor contained in the first region 61 include an yttrium aluminum garnet-based phosphor (for example, (Y,Gd)₃(Al,Ga)₅O₁₂:Ce). According to such a configuration, white light is obtained by color-mixing of blue light that is transmitted through the first region 61 and yellow light emitted from the phosphor contained in the first region 61.

The second region 62 of the light-transmissive portion 60 can function as an adhesive layer that bonds the light-transmissive portion 60 and the light-emitting elements 30 together. For example, the second region 62 may use at least one type of adhesive selected from the group consisting of a silicone-based adhesive, an epoxy-based adhesive, and an acrylic-based adhesive. The second region 62 is preferably a thin film having a thickness of about 1 μm to improve the transmittance of light incident on the light-transmissive portion 60.

### Wire

For the wire 70, metals such as Au, Ag, Cu, Pt, and Al and/or an alloy containing at least any of these metals can be used. In particular, Au having excellent thermal resistance and the like is preferably used. For example, the diameter of the wire 70 may be in a range from 15 μm to 50 μm. The wire 70 may extend across the long side of the substrate 10 having a substantially rectangular shape in a top view and, for example, may extend substantially orthogonal to the long side. Furthermore, among a plurality of wires 70 disposed in a row along the long side of the substrate 10, the wire 70 positioned at the center of the row may be disposed substantially orthogonal to the long side of the substrate 10 in a top view, as described above, and the wire 70 positioned at an end side of the row may be disposed obliquely to the long side of the substrate 10 in a top view. The interval in which the wires 70 are aligned in a row can be in a range from 20 μm to 100 μm.

### Covering Member

The covering member 80 is a light-shielding member covering the wires 70 located on an outer side of the element placement region 10r. As an example, the covering member 80 is disposed in a frame shape in a top view, so as to cover the wires 70 and surround the element placement region 10r.

The covering member 80 is separated from the light-emitting elements 30 in a top view. The covering member 80 is preferably disposed so that the height of the covering member 80 (that is, the distance from the upper surface 20a of the package substrate 20 to the upper surface of the covering member 80) is maximized directly above a top portion of each of the wires 70. In other words, the covering member 80 is preferably disposed so that a top portion of the covering member 80 overlaps with the top portion of the wire 70.

Examples of the covering member 80 include a resin containing a filler having light-shielding properties. Examples of the resin for a base material that can be used include a silicone resin, a modified silicone resin, an epoxy resin, a modified epoxy resin, and an acrylic resin. Examples of the filler having light-shielding properties include a light-reflective member or a light absorbing member, which can be contained in the light-shielding portion 40 described above. Examples of the appearance color of the covering member 80 include white having excellent light reflectivity, black having excellent light absorption, and gray having both light reflectivity and light absorption. Furthermore, the covering member 80 may include a plurality of resin layers. Among these, in consideration of deterioration of the resin due to light absorption in the covering member 80, a white resin having light reflectivity is preferably used at least on the outermost surface of the covering member 80.

The light-emitting device 1 having the configuration described above can be used as a light source of a vehicular headlight, for example. For example, the light-emitting device 1 can be used as a light source that can radiate light by selecting an irradiation region as in a headlight having an adaptive driving beam (ADB) function.

### Method of Manufacturing Light-Emitting Device 1

Hereinafter, each manufacturing step in the method of manufacturing the light-emitting device according to the embodiment will be described with reference to the drawings.

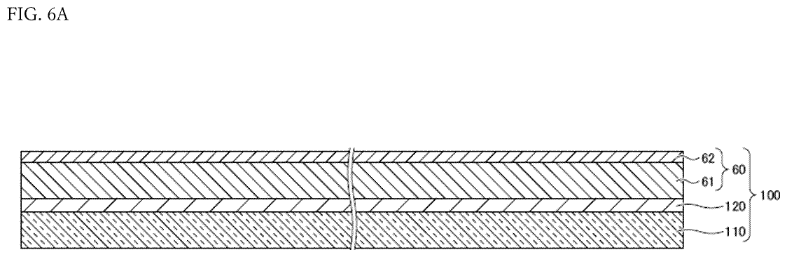

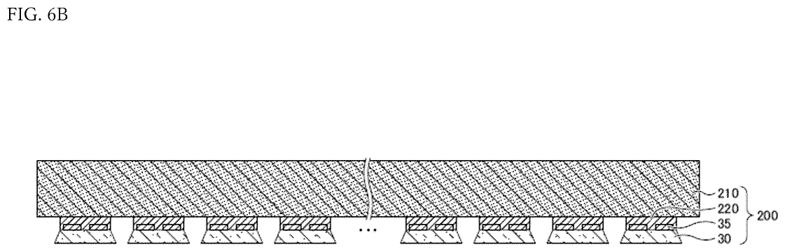

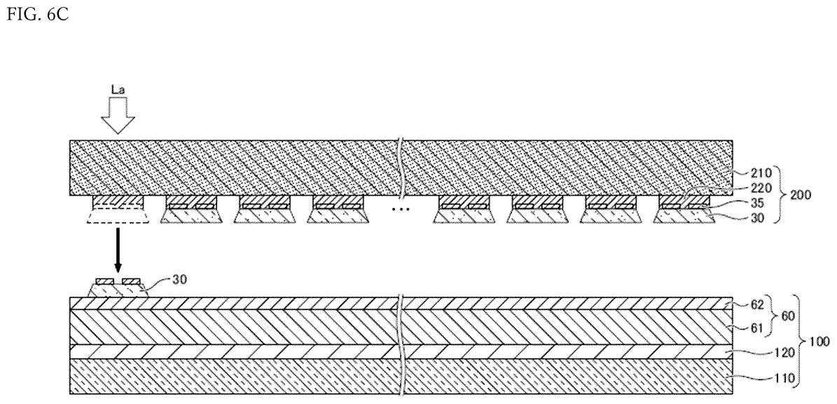

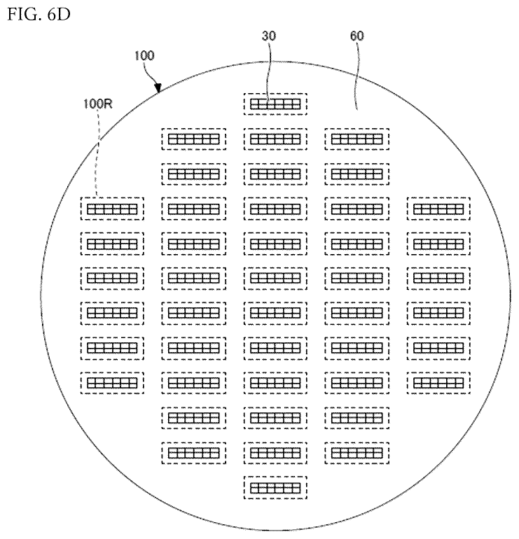

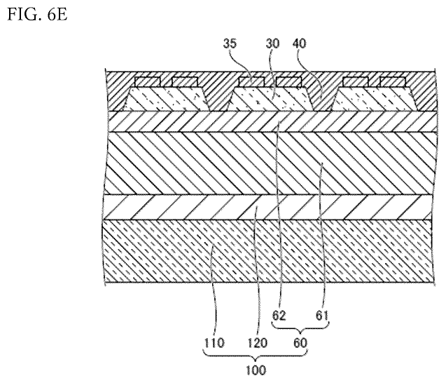

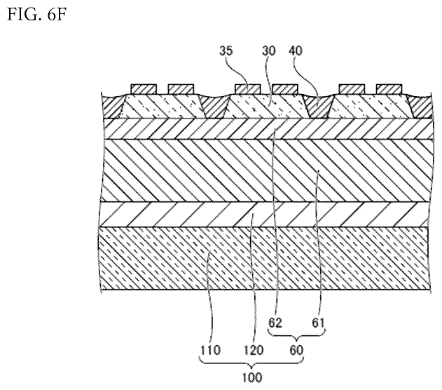

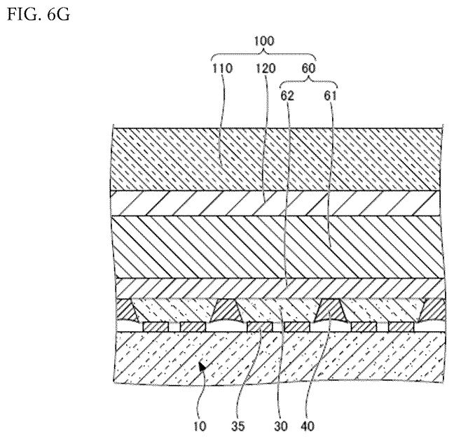

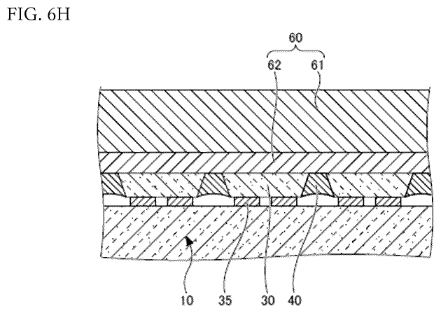

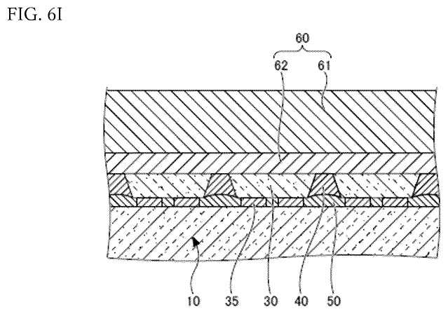

FIGS. 6A to 6C, and FIGS. 6E to 6I are cross-sectional views schematically illustrating the manufacturing steps of the light-emitting device according to the present embodiment. FIG. 6D is a top view schematically illustrating a manufacturing step of the light-emitting device according to the present embodiment. For convenience, FIGS. 6E to 6I illustrate an enlarged view of a part of the cross section illustrated in FIGS. 6A to 6C.

### Step of Providing First Structure

First, as illustrated in FIG. 6A, a first structure 100 including a first support substrate 110, a release portion 120, and the light-transmissive portion 60 in this order is provided. In the illustrated example, the light-transmissive portion 60 includes the first region 61 disposed on the release portion 120 and including the wavelength conversion member, and the second region 62 not including the wavelength conversion member. When there is no need for wavelength conversion, the light-transmissive portion 60 may not include the first region 61 including the wavelength conversion member.

Specifically, first, the first support substrate 110 is provided, and the release portion 120 is formed on an upper surface of the first support substrate 110. The upper surface of the first support substrate 110 is flat. The release portion 120 is preferably formed by spin coating. Because an upper surface of the release portion 120 formed by spin coating on the flat upper surface of the first support substrate 110 is flat, adhesion with the light-transmissive portion 60 can be improved. In addition, with the flat upper surface of the release portion 120, an upper surface of the first region 61 formed thereon and an upper surface of the second region 62 can be flat surfaces. As the first support substrate 110, for example, a glass substrate can be used. As the release portion 120, for example, a resin member containing silicone-based resin or acrylic-based resin as a base material can be used.

Subsequently, for example, a resin containing the wavelength conversion member and having been processed into a sheet shape of a predetermined size is provided to serve as the first region 61 of the light-transmissive portion 60. Then, the resin containing the wavelength conversion member is disposed on the upper surface of the release portion 120. The resin containing the wavelength conversion member may be fixed on the release portion 120 via the light-transmissive bonding member such as a resin, or may be fixed by utilizing the tackiness or the like of the resin including the wavelength conversion member without using the bonding member. The resin containing the wavelength conversion member is preferably disposed on the upper surface of the release portion 120 in a vacuum. Thus, the resin containing the wavelength conversion member can be uniformly disposed on the upper surface of the release portion 120. The resin containing wavelength conversion member may be applied onto the release portion 120 by spraying or the like instead of disposing a member processed into a sheet shape on the release portion 120. Alternatively, the resin containing the wavelength conversion member may be formed by injection molding, transfer molding, compression molding, or the like by using a mold and the like.

Subsequently, a silicone resin or the like that does not include the wavelength conversion member and that serves as the second region 62 of the light-transmissive portion 60 is provided and disposed on the first region 61. For example, a thin film having a thickness of about 1 μm can be formed as the second region 62 by diluting a silicone resin and applying the diluted silicone resin onto the first region 61 by spin coating.

In the descriptions of the manufacturing method, the expression “preparing” a member is not limited to manufacturing the member, and includes acquiring the member such as purchasing the member or otherwise obtaining the member.

### Step of Providing Second Structure

Subsequently, as illustrated in FIG. 6B, a second structure 200 including a second support substrate 210 and a plurality of light-emitting elements 30 temporarily fixed to the second support substrate 210 is provided. A step of providing the second structure 200 may be performed at a timing before, after, or at the same time as the step of providing the first structure 100.

Specifically, first, a plurality of light-emitting elements 30 are provided. Each of the plurality of light-emitting elements 30 has an upper surface and a lower surface, and includes a plurality of electrodes 35 on the lower surface side. In FIG. 6B, the light-emitting elements 30 are illustrated with their respective lower surfaces, which include the electrodes 35, facing upward. The light-emitting elements 30 can be provided by performing some or all of a plurality of steps such as a step of forming a semiconductor layered body and a step of forming the electrodes. Subsequently, a temporary fixing layer 220 is formed on the second support substrate 210, and the plurality of light-emitting elements 30 are temporarily fixed on their lower surface side to the second support substrate 210 via the temporary fixing layer 220.

Any appropriate material may be used as the material of the second support substrate 210 as long as the material has a transmittance above a certain value with respect to laser light to be described below. For example, sapphire, glass, or silicon can be used. Any appropriate may be used as the material of the temporary fixing layer 220 as the material is adapted to disappear by being irradiated with laser light, which will be described later. As a material of the temporary fixing layer 220, a material mainly composed of, for example, an epoxy resin, an acrylic resin, or a polyimide resin can be used. For example, a mixture of a fluorene-based monomer and propylene glycol monomethyl ether acetate (PGMEA) can be used. Examples of the laser light that can be used include light having a light emission peak wavelength in a wavelength range of 250 nm to 400 nm.

### Step of Transferring Plurality of Light-Emitting Elements to Light-Transmissive Portion

Subsequently, as illustrated in FIG. 6C, the first structure 100 and the second structure 200 are arranged such that the light-transmissive portion 60 provided on the first support substrate 110 of the first structure 100 and the upper surfaces of the plurality of light-emitting elements 30 having been temporarily fixed to the second support substrate 210 of the second structure 200 face each other. Then, the temporary fixing layer 220 of the second structure 200 is irradiated with laser light La via the second support substrate 210, which allows the plurality of light-emitting elements 30 to be transferred onto the second region 62 of the light-transmissive portion 60 by irradiating the temporary fixing layer 220 of the second structure 200 with laser light La via the second support substrate 210. The second region 62 has adhesive properties, which allows for reducing positional deviation of the transferred light-emitting elements 30.

The laser light La is light that can pass through the second support substrate 210 and remove the temporary fixing layer 220. In one example, only one temporary fixing layer 220 is irradiated with the laser light La in a single instance of irradiation. In a single instance of irradiation, two or more temporary fixing layers 220 may be irradiated with the laser light La, or all the temporary fixing layers 220 may be irradiated with the laser light La. Each of the temporary fixing layers 220 may be irradiated with the laser light La twice or more.

FIG. 6D is a top view schematically illustrating the first structure 100 after transferring the light-emitting elements 30. As illustrated in FIG. 6D, the first structure 100 after transferring the light-emitting elements 30 becomes, for example, a wafer including a plurality of regions 100R which are singulated and bonded to the substrate 10. For example, the regions 100R are disposed vertically and horizontally at predetermined intervals.

### Step of Forming Light-Shielding Portion

Subsequently, as illustrated in FIG. 6E, the light-shielding portion 40 containing a filler is formed between the plurality of light-emitting elements 30. Specifically, for example, a resin containing a filler and diluted with a solvent is filled between the plurality of light-emitting elements 30 by spin coating, and after the filling, the light-shielding portion 40 is formed by removing at least a part of the solvent. For example, a resin containing a filler and diluted in a range of 2- to 30-fold dilution can be used. By spin coating, the light-shielding portion 40 can be uniformly filled between the plurality of light-emitting elements 30. In addition, the resin is diluted, and thus the dilution solution is volatilized during formation of the light-shielding portion 40, which decreases the volume of the resin on its upper surface. Consequently, the filler can be filled at a high concentration between the light-emitting elements 30. For example, the filler can be mixed with the diluted resin such that the content of the filler is adjusted to be greater than 0 wt. % and equal to or less than 80 wt. %, and preferably adjusted to be in a range of 50 wt. % to 70 wt. %. Accordingly, the concentration of the filler can be increased while ensuring the filling ability between the light-emitting elements 30.

In the example illustrated in FIG. 6E, the light-shielding portion 40 is formed to cover the electrodes 35 of the plurality of light-emitting elements 30, but the light-shielding portion 40 may be formed such that upper surfaces of the electrodes 35 are exposed from the light-shielding portion 40. In a case in which the light-shielding portion 40 is formed to cover the electrodes 35, as illustrated in FIG. 6F, a step of removing at least a part of the light-shielding portion 40 to expose the electrodes 35 of the plurality of light-emitting elements 30 is further performed. The removal of the light-shielding portion 40 is performed in such a manner that at least the upper surfaces of the electrodes 35 are exposed, and may be performed in such a manner that a part or all of the lateral surfaces of the electrodes 35 are exposed. Removing at least a part of the light-shielding portion 40 allows the light-shielding portion 40 located between the light-emitting elements 30 to have, for example, a fillet shape.

In the step of exposing the electrodes 35, the light-shielding portion 40 is preferably removed by dry ice cleaning. Dry ice cleaning can be achieved by spraying fine particles of dry ice together with compressed air onto a target surface. By dry ice cleaning, damage to the light-emitting elements 30 in the removal of the light-shielding portion 40 can be reduced. In addition, in a case in which dry ice cleaning is used, fine particles of dry ice are vaporized and dispersed into the atmosphere, so that no abrasive remains after use, and a risk of contamination of the target surface can be reduced.

### Singulating Step

Subsequently, the first structure 100 including the light-emitting elements 30 and the light-shielding portion 40 illustrated in FIG. 6F is singulated into individual regions 100R illustrated in FIG. 6D. The singulation can be performed by, for example, dicing.

Step of Bonding Electrodes of Plurality of Light-Emitting Elements to Substrate Subsequently, as illustrated in FIG. 6G, the electrodes 35 of the plurality of light-emitting elements 30 are bonded to the substrate 10. Specifically, first, a wafer including a plurality of regions that are to be singulated into the substrate 10 illustrated in FIG. 2 is provided. As illustrated in FIG. 2, each region that is to be the substrate 10 includes, on an upper surface 10a side, the element placement region 10r and the first terminals 11 disposed outside the element placement region 10r. A wafer including a plurality of regions each of which will be the substrate 10 can be provided, for example, by preparing a plate-shaped support member of silicon or the like, and forming a conductive member and the first terminals 11 by a plating method, a sputtering method, or a vapor deposition method. Subsequently, in each region that is to be the substrate 10, the first structure 100 including the light-emitting elements 30 and the light-shielding portion 40 on the element placement region 10r is placed, and the electrodes 35 of the light-emitting elements 30 are bonded to the conductive member of the substrate 10. The electrodes 35 of the light-emitting elements 30, and the conductive member of the substrate 10 can be bonded by, for example, Au—Au thermocompression bonding or Au—Sn eutectic bonding. Thereafter, a plurality of regions that serve as the substrate 10 are singulated.

Step of Releasing First Support Substrate from First Structure

Subsequently, as illustrated in FIG. 6H, the first support substrate 110 is released from the first structure 100 illustrated in FIG. 6G. For example, the release portion 120 of the first structure 100 illustrated in FIG. 6G is immersed in a solution to dissolve the release portion 120, thereby releasing the first support substrate 110. In this method, compared to a method of mechanically releasing the first support substrate 110 by applying an upward force, a smaller force is applied to a bonding portion between the electrodes 35 of the light-emitting elements 30 and the conductive member of the substrate 10, so that a load on the bonding portion can be reduced.

### Step of Disposing Resin Portion

Subsequently, as illustrated in FIG. 6I, the resin portion 50 containing the filler is disposed in at least a part of the area between the plurality of light-emitting elements 30 and the substrate 10. Specifically, the resin portion 50 is disposed in which the concentration of the filler contained in the resin portion 50 is lower than the concentration of the filler contained in the light-shielding portion 40. Examples of a method of disposing the resin portion 50 include a method in which a material that will become the resin portion 50 is potted in the outer peripheral portion of the element placement region 10r of the substrate 10 and is allowed to fill a region between the plurality of light-emitting elements 30 and the substrate 10 by capillary action. After the filling, voids can be removed by curing the resin portion 50 in a vacuum oven.

As described above, in the method of manufacturing the light-emitting device 1, most of the necessary components are formed on the first support substrate 110, and then the light-emitting elements 30 and the substrate 10 are bonded to each other. This allows for a reduction in the number of steps and a reduction in costs of the light-emitting device 1. In particular, the method of manufacturing the light-emitting device 1 does not include a photolithography step, and thus does not include step of forming a resist and removing the resist that is no longer necessary after performing plating or the like. This allows for a great reduction in the number of steps.

In addition, in the method of manufacturing the light-emitting device 1, the upper surface of the light-transmissive portion 60 can be flat by forming the light-transmissive portion 60 on the flat upper surface of the first support substrate 110 via the release portion 120. For example, in a case in which the light-transmissive portion 60 includes the first region 61 including the wavelength conversion member, the upper surface of the first region 61 can be flat, so that uniform light can be extracted from the light-emitting device 1, and color unevenness can be reduced.

Similarly, the upper surface of the second region 62 can be flat, and thus by forming the light-shielding portion 40 between the plurality of light-emitting elements 30 disposed on the upper surface of the second region 62, the surfaces of the light-emitting elements 30 and the light-shielding portion 40 in contact with the upper surface of the second region 62 can be made flush with each other. Accordingly, the entire lateral surfaces of the light-emitting elements 30 are covered with the light-shielding portion 40, so that leakage light from the lateral surfaces of the light-emitting elements 30 can be reduced.

The manufacturing steps of the light-emitting device according to the present embodiment may further include the following steps.

### Step of Placing Substrate on Package Substrate

The package substrate 20 including, on the upper surface 20a side, a substrate placement region 20r on which the substrate 10 is placed, and the second terminals 22 disposed outside the substrate placement region 20r, is provided. For example, the package substrate 20 can be prepared by forming a conductive member of Cu or the like and the second terminals 22 on a flat plate-shaped support member of metal, ceramic, or the like, by a plating method, a sputtering method, or a vapor deposition method. Subsequently, the substrate 10 on which the light-emitting elements 30 are placed is placed on the substrate placement region 20r of the package substrate 20. For example, the substrate 10 and the package substrate 20 can be bonded to each other via the bonding member such as a sintered compact containing Ag or a resin material. This step can be performed, for example, after the step of disposing the resin portion.

Step of Connecting with Wire

Each of the first terminals 11 of the substrate 10 is connected to a corresponding one of the second terminals 22 of the package substrate 20 with a corresponding one of the wires 70. For example, the wire 70 is first connected to the first terminal 11 of the substrate 10 and then, is connected to the second terminal 22 of the package substrate 20. Connecting the wire 70 in this order allows the top portion of the wire 70 to be positioned closer to the first terminal 11. This can make it easier to dispose the wire 70 along a step between the substrate 10 and the package substrate 20. Thus, in a step of disposing the covering member 80 described below, the amount of resin located below the wire 70 can be reduced, and the risk of disconnection of the wire 70 due to thermal expansion of the covering member 80 can be suppressed. This step can be performed, for example, between a step of providing the substrate and the group of light-emitting elements and a step of providing a holding portion, and after the step of placing the substrate on the package substrate.

### Step of Disposing Covering Member

The covering member 80 that covers the first terminals 11, the second terminals 22, and the wires 70 is disposed on the outer peripheral portion of the upper surface 10a of the substrate 10, and on the outer peripheral portion of the upper surface 20a of the package substrate 20. For example, the covering member 80 can be disposed by supplying an unhardened resin material at a predetermined position by using a dispenser, and then, hardening the resin. This step can be performed, for example, after the step of connecting with the wire. A frame body for defining a region, in which the covering member is disposed, may be disposed on the upper surface 10a of the substrate 10, and on the upper surface 20a of the package substrate 20.

### Modified Examples

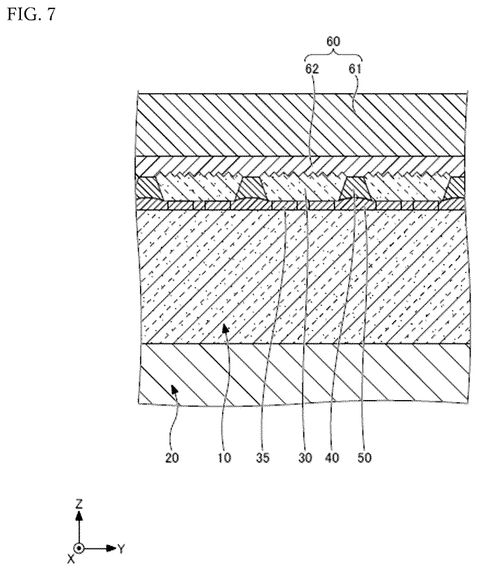

FIG. 7 is a partially enlarged view of the light-emitting elements and the vicinity of the light-emitting elements in the light-emitting device according to a first modified example. As illustrated in FIG. 7, each of the plurality of light-emitting elements 30 may have a rough upper surface. In this case, as illustrated in FIG. 7, the shape of the surface of the second region 62 opposing the rough surface of each of the plurality of light-emitting elements 30 conforms to the shape of this rough surface. That is, there is no air layer between a surface of each light-emitting element 30 and a surface of the second region 62 that face each other.

The upper surfaces of the light-emitting elements 30 can be roughened by etching, for example. The etching can be performed, for example, before the light-emitting elements 30 are temporarily fixed to the second support substrate 210. In addition, by diluting the resin and applying the diluted resin onto the first region 61 using spin coating or the like, the shape of the surface of the second region 62 can conform to the shape of the rough surface.

With the roughened upper surfaces of the light-emitting elements 30, emission areas of the light-emitting elements 30 are increased, which allows for increasing light extraction efficiency and improving the luminance of the light-emitting device 1. In addition, a contact area between the upper surfaces of the light-emitting elements 30 and a lower surface of the second region 62 can be increased, so that adhesion between the light-emitting elements 30 and the second region 62 can be improved. In a case in which the upper surfaces of the light-emitting elements 30 are rough surfaces, the surface roughness may be, for example, in a range of 0.1 μm to 3 μm in terms of arithmetic average height Ra.

It is preferable that the refractive index of the second region 62 is equal to the refractive index of the first region 61. In a case in which the upper surfaces of the light-emitting elements 30 are rough surfaces, for example, when the first region 61 is formed of a resin processed into a sheet without providing the second region 62, an air layer may be formed between the upper surface of each of the light-emitting elements 30 and the first region 61. Because the refractive index of the first region 61 is approximately 1.4 and the refractive index of the air layer is approximately 1, light emitted from the light-emitting elements 30 is less likely to pass through the air layer. Therefore, the second region 62 having the refractive index equal to that of the first region 61 is provided between the upper surfaces of the light-emitting elements 30 and the first region 61 to eliminate the air layer, so that the light emitted from the light-emitting elements 30 easily reach the first region 61. As a result, light extraction efficiency can be increased, and the luminance of the light-emitting device 1 can be improved.

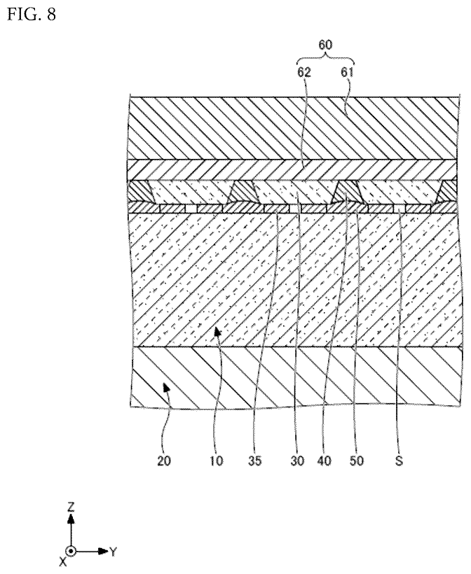

FIG. 8 is a partially enlarged view of light-emitting elements and the vicinity of the light-emitting elements in the light-emitting device according to a second modified example. As illustrated in FIG. 8, the resin portion 50 may be provided between adjacent ones of the plurality of light-emitting elements 30, and is not necessarily provided between the electrodes 35 of each of the light-emitting elements 30. In this case, a space S is provided between the electrodes 35 of each of the light-emitting elements 30. The space S can be provided by devising the shape of the electrodes 35 so that the uncured resin that becomes the resin portion 50 does not flow between the electrodes 35 of each of the light-emitting elements 30 in the step illustrated in FIG. 6I.

In a case in which there is no space S, heat generated in the light-emitting elements 30 is retained in the resin portion 50 located between adjacent ones of the electrodes 35 of the light-emitting elements 30, and thus the thermal conductivity is deteriorated. Providing the space S allows for providing the thermal conductivity as compared with the case in which the resin portion 50 is present, so that heat generated in the light-emitting elements 30 can be efficiently released toward the substrate 10.

Certain embodiments have been described in detail above. However, the invention is not limited to the above-described embodiments, and various modifications and substitutions can be made to the above-described embodiments without departing from the scope described in the claims.

What is claimed is:

1. A method of manufacturing a light-emitting device, the method comprising:
providing a first structure comprising a first support substrate, a release portion, and a light-transmissive portion, in this order;
providing a second structure comprising a second support substrate, and a plurality of light-emitting elements temporarily fixed to the second support substrate, each of the plurality of light-emitting elements having an upper surface and a lower surface, each of the plurality of light-emitting elements comprising a plurality of electrodes at the lower surface, and being temporarily fixed, at the lower surface thereof, to the second support substrate via a temporary fixing layer;
transferring the plurality of light-emitting elements to the light-transmissive portion by arranging the light-transmissive portion in the first structure and the upper surface of each of the plurality of light-emitting elements, which are temporarily fixed to the second support substrate, to face each other, and irradiating the temporary fixing layer with laser light;
forming a light-shielding portion between the plurality of light-emitting elements, the light-shielding portion containing a filler;
bonding the electrodes of the plurality of light-emitting elements to the substrate;
disposing a resin portion containing a filler in at least a part of an area between each of the plurality of light-emitting elements and the substrate, in which a concentration of a filler contained in the resin portion is lower than a concentration of a filler contained in the light-shielding portion; and
releasing the first support substrate from the first structure.

2. The method of manufacturing a light-emitting device according to claim 1, wherein:
in the step of forming a light-shielding portion, a resin containing the filler and diluted with a solvent is filled between the plurality of light-emitting elements by spin coating, and at least a part of the solvent is removed after the filling.

3. The method of manufacturing a light-emitting device according to claim 1, wherein:
in the step of forming a light-shielding portion, the light-shielding portion is formed to cover the electrodes of the plurality of light-emitting elements;
the method further comprises removing at least a part of the light-shielding portion to expose the electrodes of the plurality of light-emitting elements; and
in the step of exposing the electrodes, the light-shielding portion is removed by dry ice cleaning.

4. The method of manufacturing a light-emitting device according to claim 1 wherein:
the upper surface of each of the plurality of light-emitting elements is a roughened surface.

5. The method of manufacturing a light-emitting device according to claim 4, wherein:
the light-transmissive portion comprises:
a first region disposed on the release portion and comprising a wavelength conversion member, and
a second region not comprising a wavelength conversion member;
in the step of transferring the plurality of light-emitting elements, the plurality of light-emitting elements are transferred onto the second region; and
a refractive index of the second region is equal to a refractive index of the first region.

6. The method of manufacturing a light-emitting device according to claim 1, wherein:
the resin portion is provided between the plurality of light-emitting elements, and is not provided between the electrodes of each of the light-emitting elements.

7. The method of manufacturing a light-emitting device according to claim 1, wherein:
in the step of releasing the first support substrate, the first support substrate is released by immersing the release portion in a solution.

8. A light-emitting device comprising:
a substrate;
a plurality of light-emitting elements disposed on the substrate;
a light-shielding portion disposed between the plurality of light-emitting elements, and covering lateral surfaces of each of the plurality of light-emitting elements;
a resin portion disposed in at least a part of an area between the plurality of light-emitting elements and the substrate, and disposed between the light-shielding portion and the substrate; and
a light-transmissive portion covering upper surfaces of the plurality of light-emitting elements; wherein:
each of the light-shielding portion and the resin portion contains a filler, and a concentration of a filler contained in the resin portion is lower than a concentration of a filler contained in the light-shielding portion.

9. The light-emitting device according to claim 8, wherein:
the light-transmissive portion comprises a first region and a second region, the second region not comprising a wavelength conversion member, the second region being located on the upper surfaces of the plurality of light-emitting elements, the first region comprising a wavelength conversion member, the first region being located on the second region;
the upper surface of each of the plurality of light-emitting elements is a roughened surface; and
a shape of a surface of the second region facing the roughened surface of each of the plurality of light-emitting elements conforms to a shape of the roughened surface.

10. The light-emitting device according to claim 9, wherein:
a refractive index of the second region is equal to a refractive index of the first region.

11. The light-emitting device according to claim 8, wherein:
the resin portion is located between adjacent ones of the plurality of light-emitting elements, and is not provided between electrodes of each of the plurality of light-emitting elements.

12. The light-emitting device according to claim 8, wherein:
the light-shielding portion is in a fillet shape between adjacent ones of the plurality of light-emitting elements.
